(19) United States
(12) Patent Application Publication
(10) Pub. No.: US 2011/0220867 A1
(43) Pub. Date: Sep. 15, 2011

(54) SUPERLATTICE FREE ULTRAVIOLET EMITTER

(76) Inventors: Asif Khan, Irmo, SC (US); Qhalid Fareed, Irmo, SC (US)

(21) Appl. No.: 12/934,652

(22) PCT Filed: Mar. 27, 2009
(86) PCT No.: PCT/US09/38589

§ 371 Date: May 31, 2011

Related U.S. Application Data
(60) Provisional application No. 61/070,976, filed on Mar. 27, 2008.

(51) Int. Cl. H01L 33/06; H01L 33/18; H01L 33/32

(52) U.S. Cl. 257/13; 438/47; 438/39; 257/E33.01; 257/E33.027; 257/E33.003

(57) ABSTRACT

A light emitting device with an ultraviolet light-emitting structure having a first layer with a first conductivity, a second layer with a second conductivity; and a light emitting quantum well region between the first layer and second layer. A first electrical contact is in electrical connection with the first layer and a second electrical contact is in electrical connection with the second layer. A template serves as a platform for the light-emitting structure. The template has a micro-undulated buffer layer with AlₓIn_{y}Ga_{1-x-y}N, wherein 0<x≦1, 0≦y≦1 and 0<x+y≦1, and a second buffer layer over the micro-undulated buffer layer. The second buffer layer is made of AlₓIn_{y}Ga_{1-x-y}N, wherein 0<x≦1, 0≦y≦1, 0<x+y≦1. When an electrical potential is applied to the first electrical contact and the second electrical contact the device emits ultraviolet light.

### CROSS-REFERENCE TO RELATED APPLICATIONS

The present invention claims priority to pending U.S. Provisional Patent No. 61/070,976 filed Mar. 27, 2008.

### BACKGROUND OF THE INVENTION

The present invention relates generally to an ultraviolet light-emitting device and method of manufacturing a light-emitting device.

Group III nitride compound semiconductors such as, for instance, gallium nitride (GaN), aluminum nitride (AlN), indium nitride (InN) (hereinafter also referred to as a “Group III-nitride semiconductor” or “III-nitrides”) have been gaining attention as a material for semiconductor devices that emit green, blue or ultraviolet light. A light-emitting diode or a laser diode that emits blue light may be used for displays, for lighting and for high-density optical disk devices. A light-emitting device (which together with the acronym LED, when used herein, will for convenience also refer to both a light-emitting diode and laser diode unless otherwise specified) that emits ultraviolet radiation is expected to find applications in the field of ultraviolet curing, phototherapy, water and air purification, bio-detection, and germicidal treatment. The ultraviolet portion of the electromagnetic spectrum is often subdivided by wavelength into UVA (315-380 nm), UVB (280-315 nm) and UVC (<280 nm).

These LEDs are difficult to manufacture for a number of reasons. For example, defects arise from lattice and thermal mismatch between the group III-Nitride based semiconductor layers and a substrate such as sapphire, silicon carbide, or silicon on which they are constructed. In addition, impurities and tilt boundaries result in the formation of crystalline defects. These defects have been shown to reduce the efficiency and lifetime of LEDs and LDs fabricated from these materials. These defects have been observed for III-Nitride films grown hetero-epitaxially on the above mentioned substrates with typical dislocation densities ranging from 10⁸ cm⁻² to 10¹⁰ cm⁻² for films grown via metal-organic chemical vapor deposition (MOCVD), molecular beam epitaxy (MBE), hydride vapor phase epitaxy (HVPE) and several other less common growth techniques. Reducing the dislocation density has accordingly become an important goal.

One way to reduce the dislocation density is based on the use of epitaxial lateral overgrowth (ELOG), which is a well-known technique in the prior art. With this method, the dislocation density can be reduced to about 10⁵ cm⁻² to 10⁶ cm⁻². This method, however, has been shown to be ineffective for the growth of aluminum-containing III-Nitride based semiconductors because of the tendency for the aluminum to stick to the masked material and disrupt the lateral overgrowth. Several variations of this approach have also been demonstrated including lateral growth (PENDEO) epitaxy, and facet controlled epitaxial lateral overgrowth (FACELO) growth. All of these techniques suffer from the same limitation as the ELOG approach for aluminum containing III-Nitride materials.

Additionally, a technique called cantilever epitaxy involves growth from pillars that are defined through etching as opposed to, for example, masking.

Currently, several research groups are actively developing low-defect density AlN substrates to improve the power-lifetime performance of the deep UV LEDs. There are reports on a new air-bridge-assisted, high-temperature (1500° C.) lateral epitaxy approach to deposit 12-μm thick, high-quality AlN layers over SiC substrates as templates for the DUV LEDs.

Yet another approach to decreasing defect density is a process referred to as pulsed lateral overgrowth (PLOG) wherein preformed layers are etched to islands. By controlling the flow rate of materials a layer is coalesced over the islands. Pulsed lateral overgrowth of AlₓGa₁₋ₓN has previously been demonstrated as an approach for depositing 15-20 μm thick AlₓGa₁₋ₓN over basal plane sapphire substrates. Instead of the high temperature approach, a pulsed growth mode at 1150° C. was used to enhance Al-precursor mobilities over the growth surface. These pulsed, laterally overgrown (PLOG), AlₓGa₁₋ₓN layers show a significantly reduced number of threading dislocations (˜10⁷ cm⁻²) in the lateral-overgrowth regions, which enabled demonstration of optically-pumped lasing at 214 nm. In previous reports, the PLOG AlₓGa₁₋ₓN was grown either from shallow (˜0.3 μm) trenched sapphire or from thin AlN etched templates (˜0.3 μm).

Several other approaches to dislocation reduction have been reported that do not involve selective area growth including inserting an interlayer between the substrate and the semiconductor layer to relieve strain, filtering dislocations by bending them into each other by controlling surface facet formation or by inserting a Group III-Nitride super-lattice layer as described in Applied Physics Letters, Jul. 22, 2002; Volume 81, Issue 4, pp. 604-606, between the buffer layer and the active layer.

Accordingly, several research groups at present are developing III-nitride deep ultraviolet (DUV) light emitting diodes (LEDs) for applications in air and water purification and bio-medical systems. Milli-watt power DUV LEDs on sapphire substrates with AlGaN multiple quantum well (MQW) active regions have been previously reported for the UVA, UVB and the UVC regions. The LED design used in the prior art comprises an AlN buffer layer deposited using pulsed atomic layer epitaxy (PALE), an AlN/AlₓGa₁₋ₓN, super-lattice layer between the buffer AlN and the n-contact AlGaN layer for controlling the thin-film stress and mitigating epilayer cracking; and a p-GaN/p-AlGaN hetero-junction contact layer for improved hole injection.

A majority of the current solutions for defect mitigation involve a superlattice. The superlattice is ultimately either a sacrificial layer or it is incorporated into the finished LED with no function. A sacrificial superlattice represents material which must be manufactured and scrapped thereby increasing manufacturing and material cost. If the superlattice is included in the finished LED as the n-type doping in these superlattice is very difficult due to larger band gap. This insulating superlattice is detrimental to device performance. The thickness deviation of AlN and AlGaN leads to eventual cracking of the superlattice layer due to strain and lattice mismatch. Controlling the thickness of individual layers, quality of the epilayers and composition of AlGaN in a superlattice layer is a major issue in growing high quality crack free thick UVLEDs with superlattices.

There has been an overwhelming desire for a method of mitigating defect propagation and strain management which does not require superlattice layers and the problems formed thereby.

### SUMMARY OF THE INVENTION

The present invention is an ultra-violet light-emitting device and method for fabricating an ultraviolet light emitting device. In a preferred embodiment, the present invention is a deep ultra-violet light-emitting structure (λₚₑₐₖ=190-369 nm) with an AlₓIn_{y}Ga_{1-x-y}N, wherein 0<x≦1, 0≦y≦1, and 0<x+y≦1, quantum-well active region on a template. The template may include a substrate but has at least two buffer layers which may be repeated. One buffer layer is a micro-undulated layer and the second forms a planar layer over the first. The ultraviolet light-emitting structure deposited on top of the planar surface comprises a layered arrangement of undoped or n-type AlₓIn_{y}Ga_{1-x-y}N (wherein 0<x≦1 and 0≦y≦1, and 0<x+y≦1) layer(s), a quantum well active region and p-type AlₓIn_{y}Ga_{1-x-y}N (wherein 0≦x≦1, 0≦y≦1 and 0≦x+y≦1) materials.

The present method includes the steps of depositing a micro-undulated AlInGaN buffer on the substrate and applying an AlInGaN second buffer layer to the micro-undulated buffer layer to form a template. Next, a deep ultraviolet light emitting structure (190 nm to 369 nm) is applied onto the template.

Other features and their advantages will be apparent to those skilled in the art of semi-conductor design and light-emitting diodes in particular from a careful reading of the foregoing Detailed Description of Preferred Embodiments, accompanied by the following drawings.

Additional features, and their advantages as would be realized, are provided in a light-emitting device. The light emitting device has an ultraviolet light-emitting structure with a first layer with a first conductivity, a second layer with a second conductivity; and a light emitting quantum well region between the first layer and second layer. A first electrical contact is in electrical connection with the first layer and a second electrical contact is in electrical connection with the second layer. A template serves as a platform for the light-emitting structure. The template has a micro-undulated buffer layer with AlₓIn_{y}Ga_{1-x-y}N, wherein 0<x≦1, 0≦y≦1 and 0<x+y≦1, and a second buffer layer over the micro-undulated buffer layer. The second buffer layer is made of AlₓIn_{y}Ga_{1-x-y}N, wherein 0<x≦1, 0≦y≦1, 0<x+y≦1. When an electrical potential is applied to the first electrical contact and the second electrical contact the device emits ultraviolet light.

Yet another advantage is provided in a light-emitting device. The light-emitting device has a ultraviolet light-emitting structure on a template. The light-emitting structure has a first layer with a first conductivity, a second layer with a second conductivity and a light emitting quantum well region between the first layer and said second layer. The template has a substrate and a layered arrangement of micro-undulated layers and smooth buffer layers over the substrate. Each micro-undulated buffer layer has AlₓIn_{y}Ga_{1-x-y}N, wherein 0<x≦1, 0≦y≦1 and 0<x+y≦1. The light-emitting device further has a first electrical contact in electrical connection with the first layer and a second electrical contact in electrical connection with the second layer.

A particularly preferred embodiment is provided in a method of making a light-emitting device. The method includes the steps of: forming a template by:

applying a micro-undulated buffer layer to a substrate, wherein the micro-undulated buffer layer comprises AlₓIn_{y}Ga_{1-x-y}N, wherein 0<x≦1, 0≦y≦1, 0<x+y≦1; and applying a second buffer layer over the micro-undulated buffer layer wherein the second buffer layer comprises AlₓIn_{y}Ga_{1-x-y}N, wherein 0<x≦1, 0≦y≦1, 0<x+y≦1; placing an ultraviolet light-emitting structure on the template wherein the ultraviolet light-emitting structure has a first layer with a first conductivity and a second layer with a second conductivity; and
connecting electrically a first electrical contact with the first layer of the ultraviolet light-emitting structure and a second electrical contact with the second layer of the ultraviolet light-emitting structure.

### BRIEF DESCRIPTION OF THE DRAWINGS

FIG. 1 is a schematic cross-sectional view of an embodiment of the present invention.

FIG. 2 is a schematic cross-sectional view of an embodiment of the present invention.

FIG. 3a-c are schematic cross-sectional views of an embodiment of the present invention.

FIG. 4 is a schematic cross-sectional view of an embodiment of the present invention.

### DETAILED DESCRIPTION OF PREFERRED EMBODIMENTS

The present invention is directed to a light-emitting device (LED) and a method for making an LED, particularly one that emits deep ultraviolet light. In particular, it is directed to a template with an improved buffer wherein propagation of dislocations and strain is mitigated by the buffer layer. The template serves as a platform for an ultraviolet light-emitting structure.

The invention will be described with reference to the various figures forming an integral part of the instant disclosure. The figures, and descriptions thereof, refer specifically to preferred embodiments without limit thereto. Throughout the figures similar elements will be numbered accordingly.

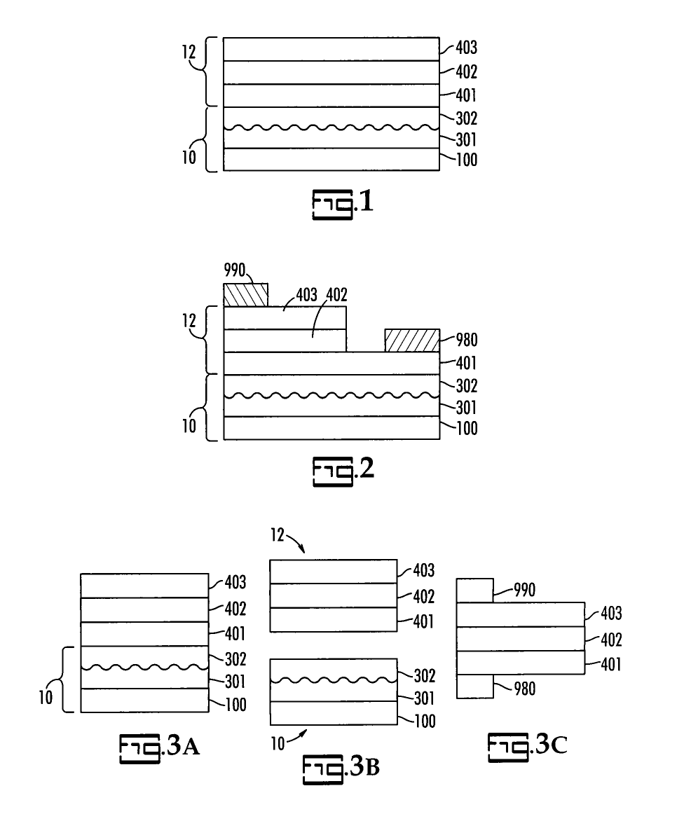

An embodiment of the invention will be described with reference to FIG. 1 wherein a schematic cross-sectional view is provided. In FIG. 1, a template, 10, includes a substrate, 100. A micro-undulated buffer layer, 301, is added onto the substrate. The micro-undulated layer will be more fully described herein. A second buffer, 302, is applied to the first buffer. The second buffer layer forms a smooth surface upon which subsequent layers are formed. The substrate, 100, first buffer, 301, and second buffer, 302, taken together are referred to herein as a template. In an alternate embodiment the arrangement of micro-undulated layer and second buffer layer may be repeated such that a second micro-undulated layer is formed on the second buffer layer followed by an additional layer to form a smooth surface. This alternate layering of micro-undulated layer and smooth layer may be repeated multiple times.

An ultraviolet light-emitting structure, 12, is applied to the template, 10. In general, the ultraviolet light-emitting structure comprises a pair of semiconductor layers of opposing polarity separated by a quantum well layer. Each layer will be described further herein. The order of the semiconductor layers is not particularly limited with the proviso that eventual biasing is applied correctly. For the purposes of discussion the n-type semiconductor will be described as being deposited initially with the understanding that the reverse could be done in an analogous fashion.

The first semiconductor layer, 401, having a first type of conductivity is applied to the template. Though illustrated as a single layer the first semiconductor layer may be multiple layers wherein each layer has an elemental composition differing, or the same as, one or more adjacent layers.

A quantum well, 402, is applied to the first semiconductor layer, 401. The quantum well, though illustrated as a single layer, preferably comprises several layers forming a quantum-well region. It is most preferred that the quantum well have an emission spectrum ranging from 190 nm to 369 nm. The quantum well preferably comprises Al_{X}In_{Y}Ga_{1-X-Y}N wherein 0≦x≦1, 0≦y≦1, and 0≦x+y≦1. The quantum well preferably has a surface and a band gap. A barrier layer is preferably on the surface of the quantum well and more preferably the quantum well region begins and terminates with said barrier layer. The barrier layer is made of Al_{X}In_{Y}Ga_{1-X-Y}N wherein 0<x≦1, 0≦y≦1 and 0<x+y≦1 and has a band gap which is larger than the band gap of the quantum well. In one embodiment the quantum layer comprises alternating layers comprising Al_{X}In_{Y}Ga_{1-X-Y}N wherein 0≦x≦1, 0≦y≦1, and 0≦x+y≦1.

The quantum well region begins and terminates with the barrier layer. The barrier layer preferably includes Al_{X}In_{Y}Ga_{1-X-Y}N wherein 0<x≦1, 0≦y≦1 and 0<x+y≦1 and the quantum well and barrier layer have different compositions. The quantum well region preferably comprises a single quantum well and multiple quantum well layers. In one embodiment the quantum well is preferably doped with at least one n-type dopant with the most preferred intentional dopants selected from the group consisting of silicon, oxygen and indium and un-intentional doped carbon. In another embodiment the quantum well is doped with at least one p-type dopant preferably selected from the group consisting of magnesium, zinc and beryllium. In another embodiment the quantum well is doped with at least one n-type and at least one p-type dopant. It is particularly preferred that the quantum well region produces ultra-violet photons. In a preferred embodiment the quantum well region emits with a wavelength λ in the range 190 nm≦λ≦240 nm. In another preferred embodiment the quantum well region emits with a wavelength λ in the range 240 nm≦λ≦280 nm. In another preferred embodiment the quantum well region emits with a wavelength λ in the range 280 nm≦λ≦320 nm. In another preferred embodiment the quantum well emits with a wavelength λ in the range 320 nm≦λ≦369 nm.

A second semiconductor layer, 403, having a second type of conductivity than the first semiconductor layer is applied on the quantum well. Two metal contacts are ultimately applied to this construction, one to the semiconductor layer having the first type of conductivity and the other to the semiconductor layer having the second type of conductivity, to complete the LED. Each of these layers, and formation of contacts thereto will be described in detail below.

The micro-undulated layer is defined as a layer with a root mean square surface roughness (Rᵣₘₛ) of at least 10 Angstroms to no more than 10 μm. More preferably, the micro-undulated layer has a surface roughness of 10 angstrom to 2 μm. The micro-undulated layer thickness is a function of the roughness and is at least slightly larger than the Rᵣₘₛ roughness. If the layer thickness is less than the roughness portions of the substrate may be left uncovered which is highly undesirable. If the layer thickness is much higher than the roughness no further benefit is obtained.

The micro-undulated layer may be bound by crystallographic faces with (0001), (1-100), (1011), (1-102), (11-20, (11-22) facets being most preferred.

The micro-undulated layer is deposited by controlling the flow of group III (Ga, Al and In) precursors and Ammonia (NH₃). In one embodiment of invention, the micro-undulated layer is deposited at temperature ranging from 400-1000° C.

In another embodiment, the micro-undulated layer is deposited at a high V/III ratio ranging from 1000 to 500,000. A group V precursor such as NH₃ or Nitrogen is modulated by decreasing and increasing the flux.

The micro-undulated layer preferably has a growth rate of about 60 Å to about 100 μm per hour with at least 0.2 μm per hour being most preferred.

The micro-undulated layer is preferably an AlGaN layer with ammonia flux flown constantly while the Group III precursor (Al and Ga in this case) is modulated by increasing or decreasing the sources flowing into chamber. The time taken to increase or decrease the flux ranges from at least 1 sec to about 120 secs and the flow is preferably stabilized at the increased or decreased flow conditions for at least 1 sec to about 120 secs.

The group III precursor is preferably flown constantly while the group V precurors such as NH₃ or nitrogen is modulated from 50 standard cubic centimeters per minute (sccm) to 10,000 sccm. The time taken to increase or decrease the group V flux ranges from at least 1 sec to about 120 secs and is stabilized at the increased or decreased flow conditions for at least 1 sec to 120 secs.

In another way of depositing micro-undulated layer, the group III and group V precursor is flown constantly while the temperature is modulated from 400 to 1000° C. The conditions are created such that the micro-undulated surface formed.

The second buffer layer is a smooth layer characterized by a root mean square surface roughness (Rᵣₘₛ) of less than 30 Angstroms and more preferably less than 10 Angstroms. A roughness of about 2-3 Angstroms has been successfully demonstrated. The second buffer layer thickness is a function of the roughness of the underlying micro-undulated layer with a thickness sufficiently thick to form a continuous layer being necessary. If the layer thickness of the second buffer layer is to small an adequate smoothness can not be obtained. If the layer thickness is too large no further benefit is obtained.

The second buffer layer is formed over the micro-undulated layer. The second buffer layer is deposited by controlling the flow of group III (Ga, Al and In) precursors and Ammonia (NH₃). In one embodiment of invention, the second buffer layer layer is deposited at temperature ranging from 800-1300° C.

The second buffer layer is also defined as a layer having at least one surface preferably selected from (001), (110), (101), (102) or (114) facets.

The second buffer layer is deposited at a variable V/III ratio ranging from 0 to 100000. A group V precursor such as NH₃ or Nitrogen is modulated by decreasing and increasing the flux.

The second buffer layer preferably has a growth rate of at least 0.01 μm hour and root mean square roughness ranging from 1 Å to 100 Å.

The second buffer layer is preferably an AlGaN layer with ammonia flux flown constantly while the Group III precursor (Al and Ga in this case) is modulated by increasing or decreasing the sources flowing into chamber. The time taken to increase or decrease the flux range from at least 1 sec to 60 secs and stabilize at the increased or decreased flow conditions for same flow for at least 1 sec to 120 mins.

The group III precursor can be flown constantly while the group V precursor, such as NH₃ or Nitrogen, is modulated from 0 sccm to 50,000 sccm. The time taken to increase or decrease the group V flux range is at least 1 sec to about 120 secs and the flow is preferably stabilized at the increased or decreased flow conditions for at least 1 sec to about 120 secs.

In another way of depositing buffer, the group III and group V precursor is flown constantly while the temperature is modulated from 800 to 1300 C. The conditions are created such that the smooth surface is formed.

While not limited to any theory, it is hypothesized that the second buffer layer coalesces over the micro-undulated layer thereby mitigating dislocation defects in the underlying crystalline lattice.

Surface roughness, as referred to herein, is an arithmetic average of absolute values of vertical deviation of the roughness profile from the mean line which is referred to in the art as Rₐ. Surface roughness is measured in accordance with the ASME Y14.36M-1996 standard.

Each layer, other than the substrate, is made of a Group III-nitride, preferably AlₓIn_{y}Ga_{1-x-y}N (wherein 0<x≦1, 0≦y≦1 and 0<x+y≦1). The precursor sources include a metal-organic source, ammonia, a carrier gas and, optionally, doping sources such as silane, and/or biscyclopentadienyl magnesium. The metal-organic source is preferably trimethyl aluminum, triethyl aluminum, trimethyl gallium, triethyl gallium, trimethyl boron, trimethyl iron, triethyl indium or trimethyl indium. The preferred carrier gas is hydrogen and/or nitrogen.

FIG. 2 illustrates template 10 with a layered, UV-emitting structure, 12, thereon, plus metal contacts 980 and 990. Except for metal contacts, 990 and 980, and the substrate, 100, all layers are preferably made of III-Nitride material.

With further reference to FIG. 2, the LED structure is grown beginning with III-Nitride first semiconductor layer, 401, with a first type of conductivity, applied directly on the second buffer, 302. It is preferred that the first semiconductor layer be an n+ layer made of AlₓIn₁₋ₓGa_{1-x-y}N (wherein 0<x≦1, 0≦y≦1 and 0<x+y≦1) formed such that the layer is transparent to the light to be emitted from the quantum well active region. Another III-Nitride layer, 402, is then formed which includes one or more barrier and one or more well sub-layers, each having different compositions such that the band-gap of the barrier layer is larger than that of the well layer. The thickness of the barrier and well layers should be between 1-200 Å. This well sub-layer has a specific band-gap and is designed to provide a region with good quantum confinement, wherein electrons and holes readily combine, preferably with radiative and non-radiative recombination but with radiative recombination dominating the non-radiative recombination. The quantum well sub-layer emits light in the range of 190 nm to 369 nm. Layer, 401, is given the first type of conductivity using silicon, or is co-doped using a combination of silicon, oxygen, and/or indium.

A p-type AlInGaN electron blocking layer, 403, is incorporated directly above the active region layer, 402, such that the band-gap of, 403, is larger than the bandgap of the barrier sublayer in, 402. Magnesium is preferably used as the p-type dopant. Additional p-type AlInGaN layers may be formed on top of, 403, such that the band-gap of the layers decreases for each subsequent layer. Subsequent layers may be one single AlInGaN layer, or may consist of a compositionally graded layer, a series of decreasing composition superlattices, or several distinct layers with decreasing bandgap to afford adequate adherence to the contact, 990.

A mesa-type LED may then be fabricated, the type shown in FIG. 2, using reactive ion etching (RIE) to access the bottom n+ layer. Finally, probe metal conducting pads, 980 and 990, are deposited on both the n+ and p+ layers, respectively. Ti/Al/Ti/Au and Ni/Au are used as metal contacts for the n- and p-contacts, respectively, however, the n-metal contacts can be made of Ti, Al, Ni, Au, Mo, Ta or any combination of these metals. The second contact, the p+ layer contact, can be made of Pd, Ni, Ag, Au, ITO, NiO, PdO or any combination of the above-mentioned metals. These contacts could be annealed in air, a forming gas, nitrogen or any combination of such. As would be apparent the layer arrangement can be reversed without consequence.

In an alternative configuration, after construction the template may be removed by polishing, etching or lifting-off using a laser. A metallic contact, 980, can be applied to the backside the n-layer, 401. The p-contact, 990, could be attached to layer, 403.

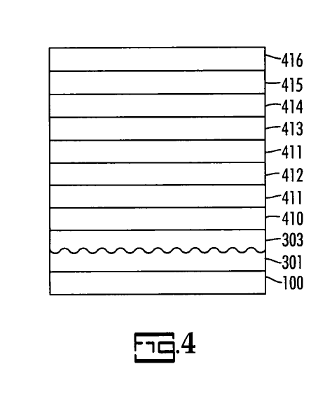

An embodiment of the invention will be described with reference to FIG. 3 wherein a schematic cross-sectional representation of an embodiment is illustrated. In FIG. 3a the template, 10, comprising a substrate, 100, micro-undulated buffer layer, 301, and second buffer layer, 302, are as described previously. Similarly, the UV-emitting structure, 12, comprising semiconductor layers, 401 and 403, and quantum layer, 402, are as described above. In FIG. 3b the template, 10, is separated from the UV-emitting structure, 12. By removing the template the terminations, 980 and 990, can be placed directly on the semiconductor layers.

An embodiment of the invention will be described with reference to FIG. 4 wherein illustrated is a cross-sectional schematic view of an embodiment of the invention. In FIG. 4 a substrate, 100, is provided as described elsewhere herein. A micro-undulated layer, 301, is on the substrate wherein the micro-undulated layer is as described above. The second buffer layer, 303, is a graded buffer layer wherein the composition gradient is altered as a function of thickness such that it is similar to that of the micro-undulated layer at the interface with that layer and is similar to the composition of a contact layer, 410, at the interface with that layer. A barrier layer, 411, is on the contact layer, 410. A quantum well layer, 412, is sandwiched between two barrier layer, 411, and a hole tunneling layer, 413, is on the final barrier layer. The quantum well layer 412 and the barrier layer 411 can be a single layer or a multiple stack layer A ramp layer 414, which helps in minimizing the lattice mismatch and strain is on the hole tunneling layer. A graded layer, 415, has a composition gradient wherein the composition is similar to the composition of the ramp layer at that interface and similar to the composition of the contact layer, 416, at that interface.

The hole tunneling layer has a preferred thickness of 1 to 1000 Angstroms and a band gap of from 0.15 eV to 2.62 eV higher than the quantum well barrier layer band gap.

It is an ongoing desire to reduce resistance in a layer, and particularly, at the interface between layers. Resistance at the contact layers is a particular concern since this resistance is a source of heat. As current is increased the heat increases. This limits the current at which an LED can be operated. With silicon doping, this is a particular problem. The incorporation of indium in a layer has been surprisingly found to significantly reduce the resistance of a layer. Indium is particularly desirable in doped layers such as silicon doped or magnesium doped layers. At a given level of silicon doping, for example, incorporation of indium reduces the resistance thereby decreasing the heat generation which allows for an increase in the current at which the LED can be operated. In a silicon doped layer the indium is preferable present in an amount of atoms ranging from 10¹⁵/cm³-10²⁴/cm³. In a magnesium doped layer the indium is preferably present in an amount of atoms ranging from 10¹⁵/cm³-10²⁴/cm³.

Although preferably made of sapphire, the substrate may be made of silicon carbide, GaN, AlN, AlGaN, InN, InGaN, AlInGaN, Silicon, GaAs, LiAlO₃, LiGaO₃, ZnO, or a metal. In addition, the substrate has a crystallographic orientation along the C-plane, A-plane, M-plane or R-plane and has a mis-orientation ranging from 0.0° to 10° from its axis. The substrate preferably has a root mean square roughness ranging from 1 Å to 100 micron.

It will be apparent to those skilled in the art of ultraviolet light-emitting diodes and laser diodes that many modifications and substitutions can be made to the preferred embodiments described herein without departing from the spirit and scope of the present invention which is specifically set forth in the appended claims.

What is claimed is:

1. A light-emitting device comprising:
a. an ultraviolet light-emitting structure having
i. a first layer with a first conductivity;
ii. a second layer with a second conductivity; and
iii. a light emitting quantum well region between above said first layer and second layer;
b. a first electrical contact in electrical connection with said first layer;
c. a second electrical contact in electrical connection with said second layer; and
d. a template serving as a platform for said light-emitting structure, said template comprising:
i. a micro-undulated buffer layer comprising AlₓIn_{y}Ga_{1-x-y}N, wherein 0<x≦1, 0≦y≦1 and 0<x+y≦1, and
ii. a second buffer layer over said micro-undulated buffer layer, said second buffer layer being made of AlₓIn_{y}Ga_{1-x-y}N, wherein 0<x≦1, 0y≦1, 0<x+y≦1; and
whereby, when an electrical potential is applied to said first electrical contact and said second electrical contact said device emits ultraviolet light.

2. The light-emitting device of claim 1 wherein said micro-undulated layer has a surface roughness of at least 10 Angstroms to no more than 10 μm.

3. The light-emitting device of claim 2 wherein said micro-undulated layer has a surface roughness of at least 0.05 μm to no more than 2 μm.

4. The light emitting device of claim 1 wherein said micro-undulated buffer layer comprises of at least one crystallographic plane selected from the group consisting of (0001), (1-100), (1011), (1-102) and (11-20).

5. The light-emitting device of claim 1 wherein said second buffer layer has a surface roughness of less than 30 Angstroms.

6. The light-emitting device of claim 5 wherein said second buffer layer has a surface roughness of less than 5 Angstroms.

7. The light-emitting device of claim 1 wherein said second buffer layer is a graded layer.

8. The light-emitting device of claim 1 wherein said first layer is doped with silicon and may be co-doped with at least one material selected from indium, oxygen, and carbon.

9. The light-emitting device of claim 1 wherein said second layer is doped with magnesium and may be codoped with at least one material selected from indium, zinc and beryllium.

10. The light-emitting device of claim 1 wherein said micro-undulated buffer layer is made of AlₓIn_{y}Ga_{1-x-y}N, wherein 0<x≦1, 0≦y≦1 and 0<x+y≦1.

11. The light emitting device of claim 10 wherein said micro-undulated buffer layer comprises Al_{X}In_{Y}Ga_{1-X-Y}N wherein 0.01<x≦1, ≦y≦1, 0.01≦x+y≦1.

12. The light emitting device of claim 11 wherein said micro-undulated buffer layer comprises Al_{X}In_{Y}Ga_{1-X-Y}N wherein 0.1<x≦1, 0≦y≦1, 0.1≦x+y≦1.

13. The light emitting device of claim 12 wherein said micro-undulated buffer comprises Al_{X}In_{Y}Ga_{1-X-Y}N wherein 0.25<x≦1, 0≦y≦1, 0.25≦x+y≦1.

14. The light emitting device of claim 13 said micro-undulated buffer layer comprises Al_{X}In_{Y}Ga_{1-X-Y}N wherein 0.5<x≦1, 0≦y≦1, 0.5≦x+y≦1.

15. The light emitting device of claim 14 said micro-undulated buffer layer comprises Al_{X}In_{Y}Ga_{1-X-Y}N wherein 0.9<x≦1, 0≦y≦1, 0.9≦x+y≦1.

16. The light emitting device of claim 15 wherein said micro-undulated buffer layer comprises Al_{X}In_{Y}Ga_{1-X-Y}N wherein 0.99<x≦1, 0≦y≦1, 0.99≦x+y≦1.

17. The light-emitting device of claim 1 wherein said first electrical contact is carried by said first buffer layer with a first conductivity.

18. The light-emitting device of claim 1 wherein said template further comprises a substrate, said micro-undulated buffer layer being between said substrate and said second buffer layer.

19. The light emitting device of claim 1 wherein said micro-undulated layer is multifaceted.

20. The light emitting device of claim 1 wherein said template further comprises a layered structure of alternating micro-undulated buffer layers and second buffer layers.

21. The light emitting device of claim 20 wherein each micro-undulated buffer layer of said micro-undulated buffer layers independently comprises AlₓIn_{y}Ga_{1-x-y}N, wherein 0<x≦1, 0≦y≦1 and 0<x+y≦1.

22. The light emitting device of claim 20 wherein each second buffer layer of said second buffer layers is independently made of AlₓIn_{y}Ga_{1-x-y}N, wherein 0<x≦1, 0≦y≦1, 0<x+y≦1.

23. The light emitting device of claim 1 wherein said quantum well region comprising alternating layers of:
a quantum well comprising Al_{X}In_{Y}Ga_{1-X-Y}N wherein 0≦x≦1, 0≦y≦1, and 0≦x+y≦1, said quantum well having a surface and a band gap; and
a barrier layer on said surface of said quantum well, said barrier layer having a band gap larger than said band gap of said quantum well, and wherein said barrier layer includes Al_{X}In_{Y}Ga_{1-X-Y}N wherein 0<x≦1, 0≦y≦1 and 0<x+y≦1, and wherein said quantum well region begins and terminates with said barrier layer.

24. The light emitting device of claim 23 wherein said quantum well region comprises a single quantum well and multiple quantum well layers.

25. The light emitting device of claim 23 wherein said quantum well and said barrier layer have different Al and Ga compositions.

26. The light emitting device of claim 23 wherein said quantum well is doped with at least one n-type and at least one p-type dopant.

27. The light emitting device of claim 26 wherein said quantum well is doped with at least one n-type dopant selected from the group consisting of silicon, indium and carbon.

28. The light emitting device of claim 26 wherein said quantum well is doped with at least one p-type dopant selected from the group consisting of magnesium, zinc and beryllium.

29. The light emitting device of claim 23 wherein said quantum well region produces ultra-violet photons.

30. The light emitting device of claim 23 wherein said quantum well region emits with a wavelength λ in the range 190 nm≦λ≦240 nm.

31. The light emitting device of claim 23 wherein said quantum well region emits with a wavelength λ in the range 240 nm≦λ≦280 nm.

32. The light emitting device of claim 23 wherein said quantum well region emits with a wavelength λ in the range 280 nm≦λ≦320 nm.

33. The light emitting device of claim 23 wherein said quantum well region emits with a wavelength λ in the range 320 nm≦λ≦369 nm.

34. A light-emitting device comprising an ultraviolet light-emitting structure on a template wherein:
said ultraviolet light-emitting structure comprises a first layer with a first conductivity; a second layer with a second conductivity; and a light emitting quantum well region between said first layer and said second layer;
said template comprises:
a substrate;
a layered arrangement of micro-undulated layers and smooth buffer layers over said substrate wherein
each micro-undulated buffer layer of said micro-undulated layers comprises AlₓIn_{y}Ga_{1-x-y}N, wherein 0<x≦1, 0≦y≦1 and 0<x+y≦1; and
said light-emitting device further comprising a first electrical contact in electrical connection with said first layer and a second electrical contact in electrical connection with said second layer.

35. The light-emitting device of claim 34 wherein said micro-undulated layer has a surface roughness of at least 10 Angstroms to no more than 10 μm.

36. The light-emitting device of claim 34 wherein said micro-undulated layer has a surface roughness of at least 0.05 μm to no more than 2 μm.

37. The light-emitting device of claim 34 wherein each said smooth buffer layer of said smooth buffer layers has a surface roughness of less than 30 Angstroms.

38. The light-emitting device of claim 37 wherein each said smooth buffer layer has a surface roughness of less than 10 Angstroms.

39. The light-emitting device of claim 34 wherein at least one smooth buffer layer of said smooth buffer layers is a graded layer.

40. The light-emitting device of claim 34 wherein said first electrical contact is carried on the said first layer with a first conductivity.

41. The light-emitting device of claim 34 wherein said substrate has crystallographic orientation along one of c-plane, A plane, M plane, R plane or a semi-polar plane.

42. The light-emitting device of claim 41 wherein said substrate has a mis-orientation of less than 10° from its axis.

43. The light-emitting device of claim 34 wherein a first micro-undulated buffer layer is grown on said substrate.

44. The light-emitting device of claim 34 wherein said substrate has a root mean square roughness of from 1 Å to 100 micron.

45. The light emitting device of claim 34 wherein said micro-undulated buffer layer comprises of at least one crystallographic plane selected from the group consisting of (0001), (1-100), (1011), (1-102), (11-20) and (11-22).

46. The light-emitting device of claim 34 wherein said second buffer layer has a surface roughness of less than 30 Angstroms.

47. The light-emitting device of claim 46 wherein said second buffer layer has a surface roughness of less than 10 Angstroms.

48. The light-emitting device of claim 34 wherein said first layer is doped with at least one material selected from indium, silicon and carbon.

49. The light-emitting device of claim 34 wherein said second layer is doped with at least one material selected from indium, magnesium, zinc and beryllium.

50. The light emitting device of claim 34 wherein at least one micro-undulated layer said micro-undulated layers is multifaceted.

51. The light-emitting device of claim 34 wherein at least one of said first electrical contact and said second electrical contact is made of Ti, Al, Ni, Au, Mo, Ta or a combination of any of these metals as a single layer or multistack layer.

52. A method of making a light-emitting device, comprising the steps of:
forming a template by:
applying a micro-undulated buffer layer to a substrate, wherein said micro-undulated buffer layer comprises AlₓIn_{y}Ga_{1-x-y}N, wherein 0<x≦1, 0≦y≦1, 0<x+y≦1; and
applying a second buffer layer over said micro-undulated buffer layer wherein said second buffer layer comprises AlₓIn_{y}Ga_{1-x-y}N, wherein 0<x≦1, 0≦y≦1, 0<x+y≦1;
placing an ultraviolet light-emitting structure on said template wherein said ultraviolet light-emitting structure has a first layer with a first conductivity and a second layer with a second conductivity; and
connecting electrically a first electrical contact with said first layer of said ultraviolet light-emitting structure and a second electrical contact with said second layer of said ultraviolet light-emitting structure.

53. The method of making a light-emitting device of claim 52 wherein said micro-undulated layer has a surface roughness of at least 10 Angstroms to no more than 10 μm.

54. The method of making a light-emitting device of claim 53 wherein said micro-undulated layer has a surface roughness of at least 0.5 μm to no more than 2 μm.

55. The method of making a light-emitting device of claim 52 wherein said second buffer layer has a surface roughness of less than 30 Angstroms.

56. The method of making a light-emitting device of claim 55 wherein said second buffer layer has a surface roughness of less than 10 Angstroms.

57. The method of making a light-emitting device of claim 52 wherein said second buffer layer is a graded layer.

58. The method of making a light-emitting device of claim 52 comprising applying said micro-undulated layer by a pulse method.

59. The method of making a light-emitting device of claim 58 wherein said pulse method includes an alteration of the group V and group III reactant ratios.

60. The method of making a light-emitting device of claim 59 wherein said group V reactant is flowed at a constant rate and flow of said group III reactant is modulated.

61. The method of making a light-emitting device of claim 52 comprising applying said second buffer layer by a pulse method.

62. The method of making a light-emitting device of claim 61 wherein said pulse method includes an alteration of the group V and group III reactant ratios.

63. The method of making a light-emitting device of claim 61 wherein said group V reactant is flowed at a constant rate and flow said group III reactant is modulated.

64. The method of making a light-emitting device of claim 52 further comprising forming at least one mesa prior to said connecting electrically.

65. The method of making a light-emitting device of claim 52 further comprising separating said ultraviolet light-emitting structure from said template.
